(19) United States
(12) Patent Application Publication
(10) Pub. No.: US 2024/0170905 A1
(43) Pub. Date: May 23, 2024

(54) LASER SYSTEM

(71) Applicant: ASML Netherlands B.V., Veldhoven (NL)

(72) Inventor: Herman Philip GODFRIED, Amsterdam (NL)

(73) Assignee: ASML Netherlands B.V., Veldhoven (NL)

(21) Appl. No.: 18/552,634

(22) PCT Filed: Mar. 7, 2022
(86) PCT No.: PCT/EP2022/055762

§ 371 Date: Sep. 26, 2023

Related U.S. Application Data
(60) Provisional application No. 63/169,750, filed on Apr. 1, 2021.

(51) Int. Cl. H01S 3/00; G02B 27/48; G03F 7/00; H01S 3/225

(52) U.S. Cl. CPC H01S 3/0057; G02B 27/48; G03F 7/70025; G03F 7/70041; G03F 7/7015; H01S 3/225

(57) ABSTRACT

A laser system comprising: a laser operable to generate a laser beam; an optical system comprising a first optical element and a second optical element; and an output through which the laser beam exits the laser system; the laser, optical system and output arranged such that the laser beam travels to the first optical element, the second optical element and the output sequentially; wherein the first optical element has a first focal length, the second optical element has a second focal length equal to the first focal length, and the second optical element is spaced from the first optical element by a distance of two times the first focal length.

### CROSS REFERENCE TO RELATED APPLICATIONS

This application claims priority to U.S. Application No. 63/169,750, filed Apr. 1, 2021, titled LASER SYSTEM, which is incorporated herein in its entirety by reference.

### FIELD

This disclosure relates to a laser system. The laser system may have application in the field of lithography and may provide a laser beam to a lithographic apparatus. The laser may, for example, comprise an excimer laser.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable the creation of increasingly smaller features. To project a pattern on a substrate, a lithographic apparatus may use electromagnetic radiation. The wavelength of this radiation determines the minimum size of features which are patterned into the resist on the substrate. Typical wavelengths currently in use are 365 nm (i-line), 248 nm, 193 nm and 13.5 nm. A laser, for example an excimer laser, can be used to provide electromagnetic radiation, in the form of a laser beam, to the lithographic apparatus. A laser beam has characteristics such as beam shape and beam size.

It may be desirable to provide a system and method for providing electromagnetic radiation having a controlled characteristic, such as beam shape and beam size, which at least partially addresses one or more problems associated with known systems and methods, whether identified herein or otherwise.

### SUMMARY

According to a first aspect of the disclosed subject-matter there is provided a laser system comprising: a laser operable to generate a laser beam; an optical system comprising a first optical element and a second optical element; and an output through which the laser beam exits the laser system; the laser, optical system and output arranged such that the laser beam propagates to the first optical element, the second optical element and the output sequentially; wherein the first optical element has a first focal length, the second optical element has a second focal length equal to the first focal length, and the second optical element is spaced from the first optical element by a distance of two times the first focal length.

The laser beam generated by the laser will, in general, have a non-zero divergence. Therefore, a cross sectional size of the laser beam will be larger at the output than at the laser. The divergence may vary over time (for example from pulse to pulse for a pulsed laser beam). Therefore the cross sectional size of the laser beam at the output may fluctuate over time. This size of the laser beam at the output is determined by the divergence of the laser beam and the distance propagated by the laser beam between the laser and the output. Furthermore, in general, a pointing direction of the laser beam generated by the laser may vary over time (for example from pulse to pulse for a pulsed laser beam). As a result, a position of the laser beam at the output will vary. This variation in position of the laser beam is determined by the variation in the pointing of the laser beam at the laser and the distance propagated by the laser beam between the laser and the output.

The optical system can be used to form an image of a first plane (located between the first optical element and the laser) in a second plane. The first plane and second plane are separated by a distance (in the direction of propagation of the laser beam) of four times the first focal length. Such an optical system reduces the effective propagation length of a laser beam emitted by the laser by a distance equal to four times the focal length. By reducing the effective propagation length, one or more characteristics of the laser beam (for example at the output) are improved for a given actual propagation length of the laser system (for example relative to an arrangement of the same physical size but omitting the optical system). The improvements in one or more characteristics may comprise a desired beam size (e.g. a reduced beam size) and/or a desired beam shape. By reducing the effective propagation length, a stability of the laser beam (for example at the output) is improved for a given actual propagation length of the laser system (for example relative to an arrangement of the same physical size but omitting the optical system). Stability may represent a variation in one or more laser beam characteristics with time (i.e. temporal variation). An improved stability may comprise: a more stable beam shape (i.e. reduced temporal variation in beam shape), a more stable beam position (i.e. reduced temporal variation in beam position) and/or a more stable beam size (i.e. reduced temporal variation in beam size). Beneficially, the inclusion of the optical system allows the laser beam to propagate over a longer path length between the laser and the output of the laser system while maintaining a desired set of characteristics and/or improved stability. In turn, this allows more physical space for optical components to be positioned between the laser and the output for a given beam stability and/or given characteristics at the output. The optical system may be referred to as a laser beam stabilization system and/or an effective propagation length reduction system.

The first focal length and the second focal length may be referred to as the focal length, f. The focal length may be a positive focal length (e.g. the first and second optical elements may comprise converging optical elements).

The optical system of the laser system according to the first aspect of the disclosed subject-matter is advantageous, as now discussed. The inventor has realized that such an optical system can form an image of any plane (which may be referred to as an object plane) before the optical system in a conjugate plane (which may be referred to as an image plane) at a distance of 4f from the object plane. As used here, a plane before the optical system may be understood to mean a plane upstream of the optical system, i.e. any plane disposed between the laser and the first optical element. This imaging occurs regardless of whether the planes coincide with a focal plane of the first or second optical element. In fact, the optical system may image a multitude of conjugate planes, e.g. a first object plane to a first image plane (at a distance of 4f from the first object plane) and a second object plane to a second image plane (at a distance of 4f from the second object plane) simultaneously. Advantageously, this allows the optical elements of the optical system to be positioned with greater flexibility between the laser and the output. Beneficially, this allows the optical elements to be placed as far apart as permitted by other constraints of the laser system, thereby further reducing the effective propagation length of the laser beam. Furthermore, this allows the optical elements to be positioned around other components that may be positioned in the laser system.

In particular, the optical system may be positioned with greater flexibility compared to known optical imaging systems. In known optical imaging systems, optical elements are typically positioned at a specific distance from an object plane of interest and an image plane of interest. The specific position of the object plane may typically be the location of a front focal plane of the optical system or a focal length of an optical element. Moving said optical elements from this specific distance typically leads to an out-of-focus image and/or diverging laser beam. Advantageously, the use of the optical system described herein removes such positioning limitations.

Since the optical system has two optical elements of equal focal length and spaced by two focal lengths, the optical system has an effective magnification of 1 or −1. The length of the optical system may be considered to be two times the focal length of the first and second optical elements. The focal length of the first and second optical elements may be selected so as to maximize the length of the optical system given the spatial requirements of the laser system.

It will be appreciated that the laser beam propagating to the first optical element, the second optical element and the output sequentially is intended to mean that the laser beam propagates to the first optical element, second optical element and output in order. That is, the first optical element receives the laser beam from the laser, the second optical element receives the laser beam from the first optical element, and the output receives the laser beam from the second optical element. Each element (first optical element, second optical element and output) may receive the laser beam directly from the preceding element or indirectly (e.g. via an intervening component). Preferably, though not essentially, the second optical element may receive the laser beam directly from the first optical element.

It will be appreciated that, as the laser beam propagates to the first optical element, the second optical element and the output sequentially, and as the laser beam exits the laser system through the output, the laser beam propagates only once through the optical system. That is, the laser beam propagates to each of the first optical element, second optical element and output once only (in order). That is, the laser beam (or any significant portion of) does not propagate to the first optical element, second optical element or output twice (for example there is no recirculation of the laser beam or any significant portion thereof through the optical system). Furthermore, the laser beam is not split into multiple components which pass through optical system via different routes. This may also be referred to as the laser beam propagating in a linear manner (or linearly) though the laser system. This may also be referred to as the laser beam propagating singly through each of the first optical element, second optical element, and output. A laser beam propagating in a linear manner is distinct from a laser beam propagating circularly or repeatedly through portions of the laser system.

The first optical element may be arranged to receive substantially all of the laser beam. Similarly, the second optical element may be arranged to receive substantially all of the laser beam. It should be understood that some losses are experienced in any laser system so substantially all may be considered representative of ‘all’ of a laser beam when losses are taken into consideration, but does not include significant or planned removal of a portion of the beam. That is, no substantial portion of the laser beam is removed (e.g. using a beam splitter or otherwise) prior to the laser beam being received by the first optical element. In other words, there is no beam splitter arranged directly before the first optical element.

The laser beam comprises radiation. The laser beam may comprise pulses of radiation or continuous radiation. The optical elements may comprise lenses and/or mirrors.

The laser may comprise an excimer laser. Excimer lasers are known to generate laser beams with pointing errors and/or fluctuations and high divergence. The aforementioned optical system is particularly beneficial when used with excimer lasers due to its ability to improve laser beam characteristics and stability (e.g. improve and/or stabilize beam position, size and shape).

The laser system may further comprise a pulse stretcher for increasing a pulse length of a pulse in the laser beam. The pulse stretcher may comprise one or more beam splitters and one or more delay lines. The pulse stretcher may be arranged to receive an input pulse to convert the input pulse into a pulse train. Increasing the pulse length may reduce the effect of speckle, for example as different temporal portions of a pulse may have a different speckle pattern. A pulse stretcher may be particularly beneficial when used in combination with a lithographic apparatus, as lithographic exposures may be adversely affected by speckle. In some situations, due to space constraints in the laser system, it may not be possible for a pulse stretcher to be disposed physically between the laser and the output of the laser system. It may therefore be necessary to increase the laser propagation distance in order to direct the laser beam to a pulse stretcher disposed elsewhere, for example due to space constraints in the laser system. The use of an optical system according to the first aspect may beneficially reduce the effective propagation length of the laser beam, enabling additional components such as pulse stretchers to be used while still providing improved beam stability and/or improved beam characteristics compared to when using a laser system without an optical system. Further, it provides greater flexibility in the positioning of such additional components such as pulse stretchers while maintaining a desired beam stability and/or laser beam characteristics at the output of the laser system.

As discussed above, the optical system reduces an effective propagation distance between the laser and the output. This allows for a larger physical distance between the laser and the output (for a given beam stability/characteristics at the output). In turn, this allows more physical space for the pulse stretcher to be accommodated. Additionally or alternatively, it allows for greater freedom for positioning the pulse stretcher. For example, this may allow for steering optics to direct the laser beam to and from a pulse stretcher that is not disposed physically between the laser and the output without sacrificing the stability or beam characteristics of the laser beam at the output due to this increased physical optical path.

The pulse stretcher may be arranged between the laser and the first optical element. Between should be interpreted with respect to the path of propagation of the laser beam. That is, the laser beam propagates from the laser to the pulse stretcher then from the pulse stretcher to the first optical element. In this arrangement, the first optical element receives the laser beam indirectly from the laser. The output of the pulse stretcher comprises substantially all of the pulse of the laser beam (minus any unintentional losses e.g. due to mirror absorption) such that the first optical element receives substantially all of the pulse. That is, substantially all of the (total) power of the input pulse is transferred into the pulse train, such that the first optical element receives substantially all of the (total) power of the input pulse. The pulse stretcher may have no overall focusing power. The pulse stretcher may have an effective propagation length of zero. The output of the pulse stretcher may comprise a substantially collimated laser beam.

A pulse stretcher reduces the peak power of a pulse. In this arrangement, lower peak powers are incident on the optical elements of the optical system. Beneficially this arrangement may reduce damage and hence increase the lifetime of the optical system.

The pulse stretcher may comprise a pulse stretcher output through which a pulse of increased pulse length may exit the pulse stretcher. The first optical element may be located proximal to the pulse stretcher output. By positioning the first optical element close to the pulse stretcher output, the distance propagated by the laser beam outside of the optical system is reduced. By reducing the distance propagated by the laser beam outside of the optical system, the stability and/or characteristics of the laser beam are improved. This reduction is possible due to imaging properties of the optical system.

It will be appreciated that by positioning the first optical element close to the pulse stretcher output, the pulse stretcher output may be disposed between the front focal plane of the first optical element and the first optical element. This is possible due to the realization by the inventor that the optical system can form an image of any plane before the optical system in a conjugate plane after the optical system.

The distance between the pulse stretcher output and the first optical element may be less than the first focal length. This arrangement is possible due to imaging properties of the optical system (the optical system can image any plane before the optical system to a conjugate plane, regardless of whether the planes coincide with a focal plane of the first or second optical element). The optical system provides greater flexibility when arranging the laser system.

The second optical element may receive the laser beam directly from the first optical element. That is, it may be that there are no intervening components between the first and second optical elements. As the laser beam is focused between the first and second optical elements, the energy fluence (energy per unit area) is high between them. Having no intervening components may beneficially reduce component damage and/or reduce absorption of the laser beam.

The laser system may further comprise a housing within which the laser and the optical system are disposed. The housing may comprise an exit aperture at or proximal to the output of the laser system. The second optical element may be located proximal to the exit aperture. The housing may be considered to generally surround the laser and the optical system. By positioning the second optical element close to the exit aperture, the distance travelled by a laser beam outside of the optical system prior to exiting the laser system is reduced. By reducing the distance travelled by the laser beam outside of the optical system, the stability and/or beam characteristics of the laser beam at the exit aperture are improved. This reduction is possible due to imaging properties of the optical system.

The distance between the exit aperture and the second optical element may be less than the first focal length. This arrangement is possible due to imaging properties of the optical system (the optical system can image any plane before the optical system to a conjugate plane, regardless of whether the planes coincide with a focal plane of the first or second optical element).

The laser system may further comprise a second optical system comprising a third optical element and a fourth optical element. The third optical element may have a third focal length. The fourth optical element may have a fourth focal length equal to the third focal length. The fourth optical element may be spaced from the third optical element along the optical axis by a distance of two times the third focal length. The third focal length may be equal to the first focal length or may be different. The second optical system may be located in one of the following locations: between the laser and the (first) optical system, between the laser and a pulse stretcher, between the first optical system and the output of the laser system. The laser system may comprise further optical systems, for example a third optical system with a fifth focal length.

The use of more than one such optical system may advantageously allow for the effective propagation distance to be further reduced whilst still allowing for additional components (for example a pulse stretcher) without requiring the additional components to be positioned between the first and second optical element of the optical system (where they may be prone to damage due to high energy fluence).

The laser system may further comprise a second pulse stretcher. The second pulse stretcher may provide a further increase in pulse length and/or otherwise process a pulse. The second pulse stretcher may be arranged between the (first) optical system and the output. That is, the second optical element may direct the laser beam to the second pulse stretcher and the second pulse stretcher may output the laser beam to the output of the laser system. This arrangement beneficially reduces the effective propagation distance travelled by a pulse between a first pulse stretcher and a second pulse stretcher.

According to a second aspect of the disclosed subject-matter there is provided a lithographic apparatus comprising the laser system of any preceding claim. An improved stability and/or improved characteristics of a laser beam afforded by the laser system of may result in improved lithographic performance.

### BRIEF DESCRIPTION OF THE DRAWINGS

Various versions of systems and methods will now be described, by way of example only, with reference to the accompanying drawings, in which:

FIG. 1A schematically depicts a lithographic apparatus;

FIG. 1B schematically depicts a view of a known laser system according to an aspect of the disclosed subject matter;

FIG. 2 schematically depicts a new laser system;

FIG. 3 schematically depicts a second new laser system with an additional component;

FIG. 4A illustrates a simulation of an output laser beam of a laser system without an optical system as described herein;

FIG. 4B illustrates a simulation of an output laser beam of a laser system with an optical system as described herein;

FIG. 5 schematically depicts the laser system of FIG. 3 with an additional optical system.

### DETAILED DESCRIPTION

In the present document, the terms “radiation” and “beam” are used to encompass all types of electromagnetic radiation, including ultraviolet (UV) radiation or deep ultraviolet (DUV) radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

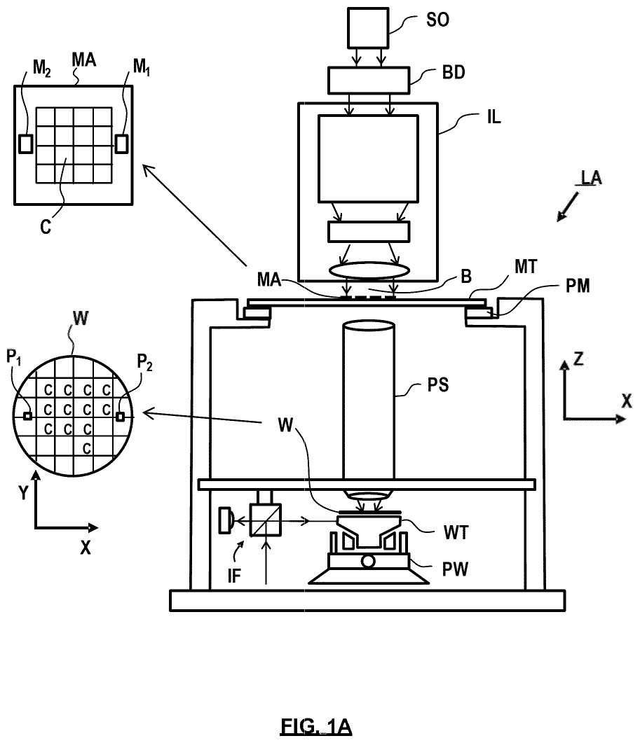

FIG. 1A schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The radiation source SO comprises a laser system. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machines, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. a mask MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around the z-axis is referred to as an Rz-rotation. The z-axis may be generally coincident with an optical axis of the lithographic apparatus (for example in a vertical direction in FIG. 1) whereas the x-axis and the y-axis may define a plane perpendicular to the optical axis (for example a horizontal plane in FIG. 1). The Cartesian coordinate system does not limit the invention and is used for clarification only. Instead, another coordinate system, such as a cylindrical coordinate system, may be used to clarify. The orientation of the Cartesian coordinate system may be different, for example, such that the z-axis has a component along the horizontal plane.

FIG. 1B schematically depicts a view of a known laser system according to an aspect of the disclosed subject matter. FIG. 1B shows an example of a known laser system 100 that is operable to produce a pulsed laser beam 110. In particular, FIG. 1B shows illustratively and in block diagram a gas discharge laser system 100. The laser beam 110 may be referred to as a light beam.

The gas discharge laser system 100 includes, a solid state or gas discharge seed laser system 115, an amplification stage, e.g., a power ring amplifier (“PRA”) stage 150, relay optics 140 and laser system output subsystem 170.

The seed laser system 115 includes: a master oscillator (“MO”) chamber 125; a master oscillator output coupler (“MO OC”) 130; and a line narrowing module (“LNM”) 120.

The master oscillator output coupler (“MO OC”) 130 may comprise a partially reflective mirror and the line narrowing module (“LNM”) 120 may comprise a reflective grating. The master oscillator output coupler (“MO OC”) 130 and the line narrowing module (“LNM”) 120 together define an oscillator cavity in which a seed laser oscillates to form a seed laser output pulse. Said oscillator cavity may be referred to as a master oscillator (“MO”).

The laser system 100 also includes a line-centre analysis module (“LAM”) 135. The LAM 135 may include an etalon spectrometer for fine wavelength measurement and a coarser resolution grating spectrometer. A MO wavefront engineering box (“WEB”) 145 serves to redirect the output of the MO seed laser system 115 toward the amplification stage 150, and may include, e.g., beam expansion with, e.g., a multi prism beam expander (not shown) and coherence busting, e.g., in the form of an optical delay path (not shown).

The amplification stage 150 includes a PRA lasing chamber 160, which may also be an oscillator, e.g., formed by seed beam injection and output coupling optics (not shown) that is incorporated into a PRA WEB 165 and is redirected back through the gain medium in the chamber 160 by a beam reverser 155. The PRA WEB 165 may incorporate a partially reflective input/output coupler (not shown) and a maximally reflective mirror for the nominal operating wavelength (e.g., at around 193 nm for an ArF system) and one or more prisms.

The solid state or gas discharge seed laser system 115, amplification stage 150 and relay optics 140 may together be considered to be a laser operable to generate a laser beam.

A bandwidth analysis module (“BAM”) 175 at the output of the amplification stage 150 receives the output laser light beam of pulses from the amplification stage 150 and may pick off a portion of the light beam for metrology purposes, e.g., to measure the output bandwidth and pulse energy. The output light beam of pulses then passes through an optical pulse stretcher (“OPuS”) 180. One purpose of the OPuS 180 may be, e.g., to convert a single output laser pulse into a pulse train. Secondary pulses created from the original single output pulse may be delayed with respect to each other. By distributing the original laser pulse energy into a train of secondary pulses, the effective pulse length of the laser can be expanded and at the same time the peak pulse intensity reduced. The output light beam of pulses then passes through an output combined autoshutter metrology module (“CASMM”) 185, which may also be the location of a pulse energy meter. The OPuS 180 can thus receive the laser beam from the PRA WEB 165 via the BAM 175 and direct the output of the OPuS 180 to the CASMM 185. Other suitable arrangements may be used in other embodiments.

The PRA lasing chamber 160 and the MO 125 are configured as chambers in which electrical discharges between electrodes may cause lasing gas discharges in a lasing gas to create an inverted population of high energy molecules, including, e.g., Ar, Kr, and/or Xe, to produce relatively broad band radiation that may be line narrowed to a relatively very narrow bandwidth and centre wavelength selected in a line narrowing module (“LNM”) 120, as is known in the art.

Typically the tuning takes place in the LNM 120. A typical technique used for line narrowing and tuning of lasers is to provide a window at the back of the laser's discharge cavity through which a portion of the laser beam passes into the LNM. There, the portion of the beam is expanded with a prism beam expander and directed to an optical element, such as a grating which reflects a narrow selected portion of the laser's broader spectrum back into the discharge chamber where it is amplified. The laser is typically tuned by changing the angle at which the beam illuminates the grating using an actuator such as, for example, a piezoelectric actuator. Alternatively a transmissive optical element, such as a prism may be used to transmit a narrow selected portion of the laser's broader spectrum back into the discharge chamber where it is amplified. The laser may be tuned by changing the angle at which the beam illuminates the prism using an actuator such as, for example, a piezoelectric actuator. The laser system 100 may be operable to generate a burst of one or more pulses having one wavelength and then be able to switch to generating a burst of one or more pulses having a different wavelength.

The radiation source SO shown in FIG. 1A and described above may comprise the laser system 100 shown in FIG. 1B.

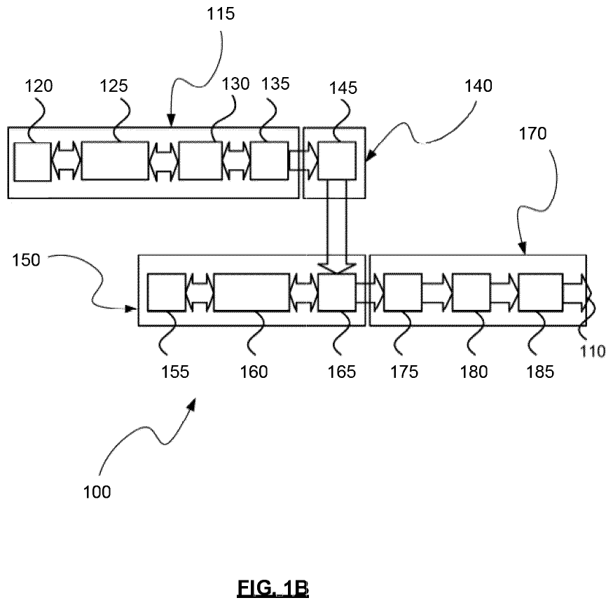

Embodiments of the present disclosure relate to novel laser systems. These novel laser systems may be generally of the type of laser system 100 shown in FIG. 1B and may comprise one or more of the features of the laser system 100 shown in FIG. 1B. Examples of such novel laser systems will now be described with reference to FIGS. 2 to 5.

FIG. 2 schematically depicts a new laser system 200. The laser system 200 may form part or all of the radiation source SO of FIG. 1A. The laser system 200 may form part or all of a laser system of the type shown in FIG. 1B and described above. As described more fully below, the laser system 200 includes a laser 210 that is operable to produce a laser beam 220 and an optical system 230 comprising a first lens 231 and a second lens 232. The laser 210 may be of the type depicted in FIG. 1B, for example comprising the solid state or gas discharge seed laser system 115, amplification stage 150 and relay optics 140.

The laser beam 220 propagates to (and propagates through) the first lens 231 and the second lens 232 before propagating to an output 240 where it exits the laser system 200.

The laser beam 220 has abeam size, beam shape and beam profile. The beam profile is a spatial intensity profile in a plane perpendicular to the direction of propagation of the laser beam 220. Examples of types of beam profile are Gaussian and top-hat. The beam shape is a shape of the laser beam 220 in a plane perpendicular to the direction of propagation of the laser beam 220. Examples of beam shape are circular and rectangular. The beam size is a size or dimension of the laser beam 220 in a plane perpendicular to the direction of propagation of the laser beam. The beam size may be characterized, for example, by a radius (e.g. for a rotationally symmetric beam shape such as a circular beam), or a distance along a major and minor axis (e.g. for a beam shape with reduced rotational symmetry such as a rectangular beam). The beam size may be referred to as a beam width. It will be appreciated by the skilled person that a laser beam typically does not have a sharply defined edge, and that the edge is defined as a region containing a certain amount of the intensity contained in the laser beam. Various conventions are used to measure and represent beam widths, for example 1/e2 (the distance between two diametrically opposite points of the beam at which the intensity is 1/e2 times the maximum intensity of the beam), FWHM (the distance between to diametrically opposite points of the beam at which the intensity is 50% of the maximum intensity of the beam), D4σ (four times the standard deviation of the intensity distribution).

The laser beam propagates generally along an optical axis. That is, the optical axis can be defined as a nominal or target path along which the laser beam propagates. Small deviations can occur, namely divergence and pointing errors, which cause a portion of the laser beam to propagate in a direction not aligned with the optical axis, as described in more detail below.

The laser beam 220 has a divergence which quantifies the increase in beam size as the laser beam 220 propagates, for example through free space. Isotropic divergence results in a laser beam increasing in beam size isotropically in all directions perpendicular to the direction of propagation of the laser beam, resulting in a laser beam which has a larger beam size as it propagates through free space. The effects of divergence typically depend on the distance propagated by the laser beam 220 (the propagation distance) in combination with the magnitude of the divergence of the laser beam 220. For a given divergence, a laser beam 220 will have a larger beam size as its distance from the laser 210 increases. Anisotropic divergence may result in a laser beam increasing in beam size by a first amount in a first direction perpendicular to the direction of propagation of the laser beam and by a second amount in a second direction perpendicular to the direction of propagation of the laser beam, hence resulting in a laser beam which changes in beam shape as it propagates through free space (e.g. a circular beam may become elliptical as it propagates), in addition to changing in beam size. The divergence of the laser beam 220 may be fixed, or it may vary over time (for example from pulse to pulse with a pulsed laser). This may be referred to as a fluctuating divergence. A fluctuating divergence typically results in a beam size and/or shape which varies over time (i.e. fluctuating beam size and/or beam shape).

The laser beam 220 may experience pointing errors wherein a portion of the laser beam 200 is emitted at a non-zero angle to the optical axis. The term optical axis is known in the art and may define a nominal or target pointing direction for the laser beam 220. Integrated over a sufficiently large time period (for example a sufficient number of pulses), the laser beam 220 may be generally rotationally symmetric about the optical axis. However, over shorter time periods (for example from pulse to pulse), the pointing direction of the laser beam 220 may vary with respect to the optical axis. Pointing errors affect a position of a beam with respect the optical axis. With no pointing errors, every portion of the laser beam 220 is directed generally along (or rotationally symmetrically around) the optical axis such that a center of the laser beam 220 may generally coincide with the optical axis. As such, with no pointing errors, as the laser beam 220 propagates (e.g. through free space) it will hit any virtual target located along the optical axis, i.e. the beam position coincides with the optical axis. With pointing errors, as the laser beam propagates (e.g. through free space), a center of the laser beam does not propagate along the optical axis but rather at a non-zero angle to the optical axis. As a result, as the propagation distance of the laser beam 220 increases, a distance between the center of the laser beam 220 and the optical axis increases. As a result, the laser beam 220 may miss (or partially miss) a virtual target located along (and centered on) the optical axis. That is, as a result of pointing errors, the beam position may be misaligned with respect the optical axis. The pointing (i.e. direction of emission with respect to the normal optical axis) of a portion of the laser beam may vary over time, leading to fluctuations in the pointing, referred to as pointing fluctuations. In particular, when the laser 210 is a pulsed laser, in general, the pointing of each pulse may vary. Pointing fluctuations can result in a beam position which varies over time. Similarly to divergence, the effects of pointing errors depend on the propagation distance of the laser in combination with the magnitude of the pointing error. Therefore, for a given pointing error, the beam position will be more misaligned with the optical axis as the laser beam propagates further from the laser 210.

The laser system 200 comprises an optical system 230 which reduces the effects of divergence and/or pointing errors. In particular, the optical system 230 reduces the effective propagation distance of the laser beam 220, thereby reducing the effects of divergence and pointing errors, which depend on the propagation distance.

The optical system 230 comprises a first lens 231 and second lens 232. The first and second lens 231, 232 have equal focal lengths f and are spaced by a distance of 2f. The first and second lenses 231, 232 have a positive focal length (i.e. are converging rather than diverging lenses). In this arrangement, the optical system 230 forms an imaging system with a total magnification of 1 (or −1).

The laser beam 220 is fairly well collimated although, as described above, the laser beam 220 has a non-zero divergence. As the laser beam 220 is incident on the first lens 231, it is focused to a plane between the first and second lenses 231, 232. The divergent laser beam after this plane is converted back into a fairly well collimated laser beam 220 (having substantially the same divergence as the incident laser beam) by the second lens 232.

The inventor has realized that such an optical system 230 forms an image of any plane (which may be referred to as an object plane) before the optical system 230 (i.e. between the laser 210 and the first lens 231) in a conjugate plane (which may be referred to as an image plane). The distance between the object plane and the image plane is equal to four times the focal length, i.e. 4f. Therefore, although the laser beam 220 propagates a distance of 4f between each pair of object and image planes, the size and position of the laser beam 220 will be the same in these two planes. As such, the effects of divergence and pointing errors are effectively zero as the laser beam 220 propagates between each pair of object and image planes. Therefore, the imaging performed by the optical system 230 is such that the effective propagation length of the laser beam 220 propagating from the laser 210 to the output 240 is reduced by four times the focal length, i.e. 4f.

This imaging occurs regardless of whether the object plane and/or image plane coincide with a focal plane of the first or second lenses 231, 232. This allows a large degree of flexibility when arranging the lenses 231, 232, for example because they can be placed anywhere between the laser 210 and the output 240, as long as they are spaced 2f from each other. The focal length f of the first and second lens 231, 232 can be selected so as to maximize the distance between the object and image planes being imaged, and therefore maximize the reduction in the effective propagation length of the laser beam 220. The effective propagation length of the laser beam 220 within the laser system 200 is equal to the actual path length of the laser beam 220 between the laser 210 and the output 240 minus 4f.

It is known that an optical system comprising one or more lenses can be used as an imaging system to form an image of one plane (which may be referred to as an object plane) in another plane (which may be referred to as an image plane). Typically, when imaging using for such optical imaging systems, as a distance from the image plane increases, the image loses contrast and will become de-focused (i.e. the light beam diverges). As such, when passing a light beam through a standard optical imaging system known in the art, it is common to require additional optics following the image plane to re-focus the light beam periodically.

As a skilled person would understand, laser beams are typically well collimated (although as discussed elsewhere in practice they have a non-zero divergence). Such a laser beam may be referred to as near-collimated or substantially collimated. The optical system 230 as described herein is arranged to form an image of a laser beam 220, such that a substantially collimated beam is imaged to a substantially collimated beam. As such, additional optics are not required for re-focusing the imaged beam. Rather, the optical system 230 can be used without additional optics to yield the advantage of improved beam characteristics and/or improved stability.

The first lens 231 receives substantially all of the laser beam 220 from the laser 210. The optical system 230 is arranged such that the laser beam 210 travels to the first lens 231, the second lens 232 and the output 240 sequentially (i.e. in order). That is, the first lens 231 receives the laser beam 220 from the laser 210, the second lens 232 receives the laser beam 220 from the first lens 231, and the output 240 receives the laser beam 220 from the second lens 232, at which point the laser beam 220 exits the laser system 200 (e.g. through an aperture (not shown) at or proximate to the output 240). As the laser beam 220 travels to the first lens 231, the second lens 232 and the output 240 sequentially, and as the laser beam 220 exits the laser system 200 through the output 240, the laser beam 220 travels only once through the optical system 200. This may be referred to as the laser beam 220 travelling linearly through the optical system (i.e. with no recirculation) and/or the laser beam 220 travelling through the first and second lenses 231, 232 and output 240 singly (i.e. with no multiple passes). In this way, substantially all of the laser beam 220 is imaged by the optical system 230 without any unnecessary losses (e.g. unnecessary losses due to absorption in optical elements and/or the removal of a portion of the beam).

The first and second lenses 231, 232 may be referred to as optical elements. In fact, a focusing optical element other than a lens may be used instead of either or both of the first and second lenses 231, 232. For example, a focusing mirror may be used as an optical element rather than a lens. It should be understood that when a mirror is used as an optical element, the laser beam 220 will propagate to and interact with (for example scatter from), rather than propagate through, the optical element. The optical elements are typically converging rather than diverging.

Laser systems typically have space constraints which, at least partially, dictate the size, shape and/or arrangement of the laser system and components therein. The space constraints can arise due to the laser system being disposed within a housing, for example for ease of transport and/or to shield the laser beam from users in the vicinity of the laser system. Such housings may be of fixed size/shape and hence dictate the placement of components disposed therein. Additionally or alternatively, space constraints may arise due to user requirements, for example the footprint and/or volume in which a user may place a laser system.

Laser systems also typically have additional components which are used to process the laser beam. For example, a laser system may comprise one or more beam expanders, pulse stretchers, beam shapers etc. FIG. 1B as described above is an example of a laser system 100 comprising additional components e.g. bandwidth analysis module 175, pulse stretcher 180, metrology module 185.

Such additional components may be placed between (i.e. along the path of the laser beam between) the laser and the laser system output. The placement of such components physically between the laser and the system output (for example in a straight line with no/little redirection of the laser beam) may be difficult or impossible, especially given the space constraints discussed above. As such, it may be desirable for components to be spaced a significant distance from the laser, and the laser beam directed (for example using mirrors) to the component(s) before being redirected towards the output of the laser system. However, with such an arrangement the laser beam propagates over a greater distance (e.g. meters or tens of meters) compared to systems with no additional components, and thereby experiences greater effects due to divergence and/or pointing errors. For example, due to the greater propagation distance, such laser systems may output a laser beam with one or more of the following: larger beam size, fluctuating beam size, undesirable beam shape fluctuating beam shape, fluctuating beam position.

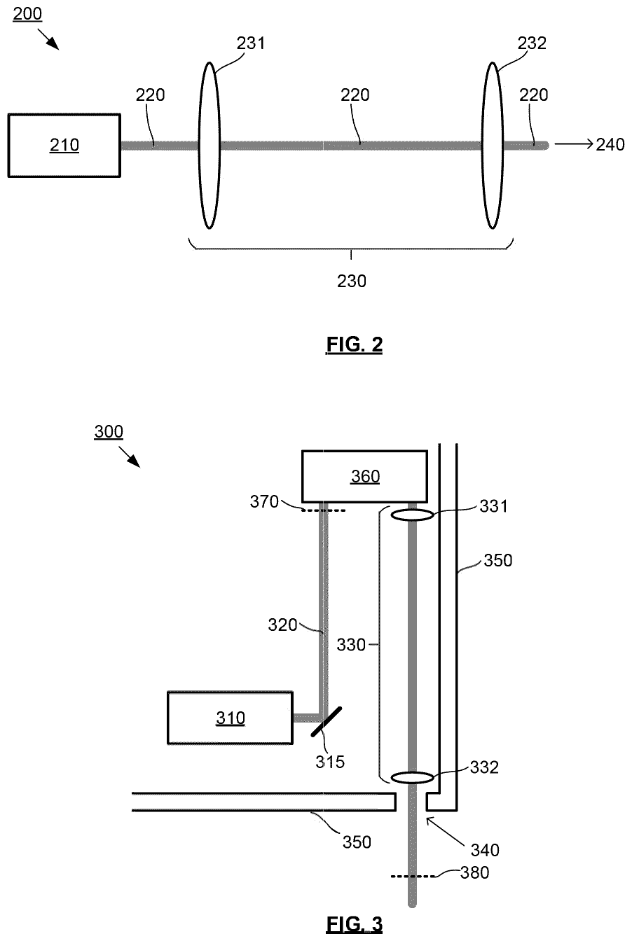

FIG. 3 schematically depicts a laser system 300 with an additional component. The laser system 300 comprises a laser 310 which emits a laser beam 320. In this example, the laser 310 is a pulsed laser which emits pulsed radiation. That is, the laser beam 320 comprises pulses of laser radiation. The laser beam 320 is directed using mirrors 315 to a pulse stretcher 360. Pulse stretchers are known in the art and are used to increase the pulse length of a pulse of radiation. For example a pulse duration may be increased from the order of tens of nanoseconds to the order of hundreds of nanoseconds. The pulse stretcher 360 may be of the type described above with reference to FIG. 1B (i.e. an OPuS 180 operable to convert a single output laser pulse into a pulse train). After passing through the pulse stretcher 360, the laser beam 320 propagates to a first lens 331 and a second lens 332 which form an optical system comparable to that described above. After propagating through the second lens 332, the laser beam 320 exits the laser system 300 through an output 340 which coincides with an exit aperture of a housing 350. The laser 310, pulse stretcher 360 and lenses 331, 332 are disposed within the housing 350.

The optical system 330 is arranged such that the laser beam 310 travels to the first lens 331, the second lens 332 and the output 340 sequentially (i.e. in order).

The pulse stretcher 360 is located in a position which is not directly between the laser beam 310 and the output 340. This may be, for example and as described above, due to space constraints. As such, the laser beam 320 propagates an additional distance away from the output 340 in order to be processed by the pulse stretcher 360, before propagating towards and through the output 340. The optical system 330 comprising first and second lenses 331, 332 is positioned so as to minimize the effective propagation length of the laser beam 320 despite the increase in its actual propagation length.

The first lens 331 is located proximal to an output of the pulse stretcher 360. As the optical system can image any pair of conjugate planes, the first lens 331 does not need to be positioned at one focal length f from the output (or a focal plane of) the pulse stretcher 360. In fact, in this arrangement an object plane being imaged by the optical system is located between the laser 310 and the pulse stretcher 360, for example as indicated by a dotted line 370 in FIG. 3. This is possible due to the imaging properties of the optical system comprising the first and second lenses 331, 332 spaced by 2f. This allows the first lens 331 to be placed very close to, for example within less than 1 focal length f of, the output of the pulse stretcher 360.

The second lens 332 is located proximal to the output 340 of the laser system 300. As the optical system can image any conjugate planes, the second lens 332 does not need to be positioned at one focal length from the output 340 of the laser system. In fact, in this arrangement the conjugate plane to the object plane represented by the dotted line 370 is located outside of the laser system 300 as indicated by a dotted line 380. Note that FIG. 3 is illustrative in nature and is not drawn to scale.

A fully flexible arrangement (i.e. where the first optical element 331 can be positioned at any distance from the output of the pulse stretcher 360 or other additional component) is possible as long as the pulse stretcher 360 (or other additional component in its place) does not influence beam parameters of the laser beam 320. For example, this could be achieved if the pulse stretcher 360 has an effective propagation length of zero. In this way, any beam parameters of the laser beam prior to the pulse stretcher 360 (e.g. the single laser pulse received by the pulse stretcher 360 from the laser 310) are replicated in the chain of pulses wherever the optical system 330 is positioned (relative to the pulse stretcher 360).

Alternatively, in some embodiments an optical element may be introduced (for example between the laser 310 and the optical system 330) that does influence parameters of the laser beam 320. For such embodiments, if there is sufficient distance between said optical element and the first lens 331 then the optical system 330 may be considered to image a real object plane before the optical system 330 onto an image plane after the optical system 330. Alternatively, the optical system 330 may be considered to image a virtual object plane before the optical system 330 onto an image plane after the optical system 330.

The first and second lenses 331, 332 are selected such that their focal lengths f allow them to be positioned 2f from each other while being positioned proximal to the output of the pulse stretcher 360 and the output 340 of the laser system 300, respectively. As such, the 4f distance by which the effective propagation length of the laser beam 320 is reduced is maximized. Therefore, the effects of divergence and pointing errors are reduced. For example, when compared to a laser system with no optical system as described herein, the laser system 300 may output a laser beam with one or more of the following: a smaller beam size, reduced beam size fluctuations, a more desirable beam shape, reduced beam shape fluctuations, reduced beam position fluctuations.

In a laser system without an optical system as described herein, sub-optimal laser beam characteristics and/or low beam stability can cause the laser beam to at least partially miss the exit aperture of a housing. This can lead to a significant portion of the laser beam being blocked from exiting the laser system, for example as portions of the laser beam may hit the housing rather than exiting through the exit aperture. Such losses can affect the efficiency of the laser system, for example on the order of 10% efficiency loss. When the laser system is used with a lithographic apparatus, any variation in such losses can affect the dose control of said lithographic apparatus which, as described below, is undesirable. A laser system 300 of the type depicted in FIG. 3, therefore, can significantly improve the efficiency of the laser system 300 because the laser beam characteristics and/or stability is improved and hence the laser beam 220 can better exit the exit aperture without being blocked by the housing 350. Furthermore, in laser systems where such sub-optimal laser beam characteristics/stability cause the laser beam to at least partially miss the exit aperture of a housing, a higher laser power may be used to offset the losses. A higher laser power typically results in increased wear and/or damage on any components in the path of the laser beam, resulting in reduced optical lifetimes of components. Therefore, a laser system 300 with the optical system 330 as described herein may beneficially increase the lifetime of components in the laser system.

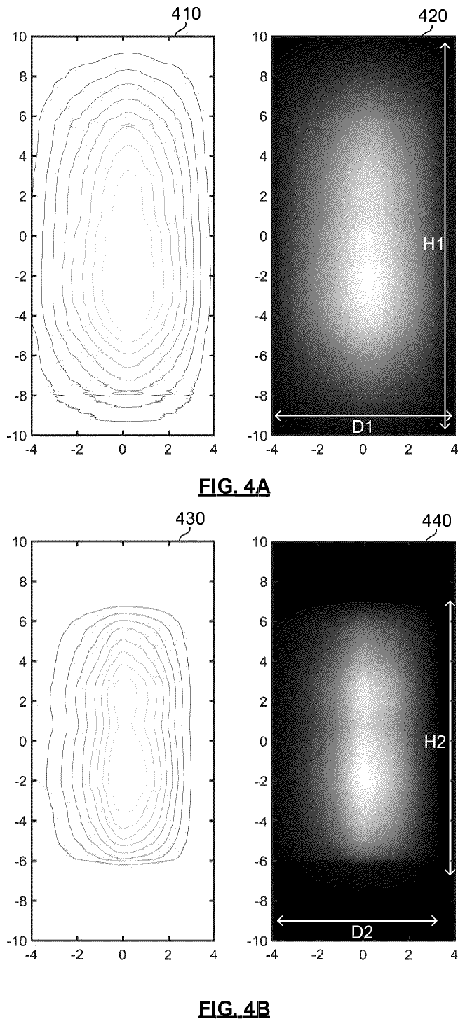

FIGS. 4A and 4B illustrate a simulation of an output laser beam of a laser system without and with an optical system 230, 330 of the type shown in FIGS. 2 and 3 and as described above, respectively. In both laser systems, the laser emits a laser beam with a top-hat profile and rectangular shape, which is achieved through the selection of the laser and various beam processing components. The only significant difference between the output laser beams of the two laser systems is the inclusion of an optical system 230, 330 as described herein. The output laser beams are shown in a plane perpendicular to the direction of propagation of the laser beam.

FIG. 4A shows a contour plot 410 and an image plot 420 which illustrate the beam profile of the simulated laser beam at the output of the laser system without an optical system (hereafter referred to as the first simulated beam). Both the contour plot 410 and image plot 420 show that the first simulated beam is generally elliptical in shape, and has a substantially Gaussian profile. The first simulated beam has a height H1 a width D1.

FIG. 4B shows a contour plot 430 and an image plot 440 which illustrate the beam profile of the simulated laser beam at the output of the laser system with an optical system (hereafter referred to as the second simulated beam). Both the contour plot 430 and image plot 420 show that the second simulated beam is more rectangular in shape than the first simulated beam. There is some curving of the ‘corners’ of said rectangle, but the shape is significantly more rectangular than the first simulated beam. The second simulated beam has a height H2 which is smaller than the height H1 of the first simulated beam. The second simulated beam has a width D2 which is smaller than the width D1 of the first simulated beam. Therefore, the second simulated beam has a smaller beam size than the first simulated beam. This demonstrates how, in this example, the laser system with an optical system 230, 330 reduces the effects of divergence, resulting in a smaller beam size and more desirable beam shape.

While not represented in the image, the stability of the second simulated beam is improved compared to the first simulated beam. That is, there is reduced temporal variation in the beam size, beam profile, beam position and beam shape of the second simulated beam compared to the first simulated beam. This demonstrates that the effects of divergence fluctuations and pointing fluctuations are reduced.

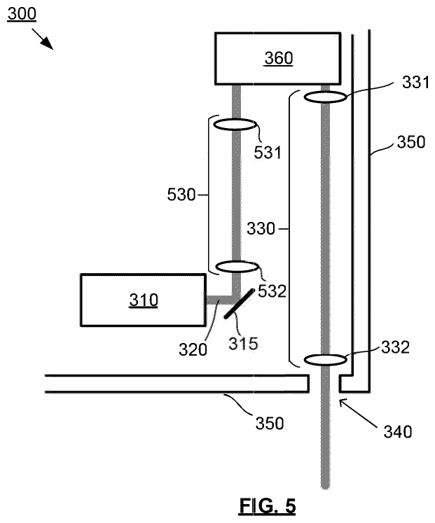

FIG. 5 schematically depicts the laser system of FIG. 3 with an additional optical system. Like parts are numbered accordingly. In this arrangement, the laser system 300 comprises a second optical system 530 comprising a third lens 531 and a fourth lens 532. The third and fourth lenses 531, 532 have equal focal lengths f2 which, in this arrangement, are different to the focal length f of the first and second lenses 331, 332. In other arrangements, a second optical system 530 may be used which comprises lenses with equal focal length to the lenses in the first optical system.

The optical system 330 is arranged such that the laser beam 310 travels to the third lens 531, the fourth lens 532 and the output 340 sequentially (i.e. in order).

By providing this second optical system 530 with third and fourth lenses 531, 532, the effective propagation distance of the laser beam 320 is further reduced by 4f2. The provision of this second optical system 530 further reduces the effects of divergence and pointing errors.

The optical systems (e.g. 230, 330, 530) described herein may be used with a range of lasers, in a range of applications which use lasers. The optical systems described herein are of particular use in lithography, for example in a lithographic apparatus such as that described with reference to FIG. 1A. For an optimal lithographic exposure, accurate control of the dose of radiation provided to a substrate is desirable. Furthermore, for an optimal lithographic exposure, the radiation provided to the patterning device and subsequently the substrate can be selected to have a specific profile (e.g. an angular distribution of light). This profile may be referred to as an illumination mode or pupil mode. Sub-optimal laser beam characteristics, can result in sub-optimal dose control and/or sub-optimal illumination modes and hence sub-optimal lithographic exposures. For high quality exposures in lithography, it is typically desirable to provide radiation (e.g. in a laser beam) with known characteristics, for example a known beam size, known beam shape, known beam position. Furthermore, for high quality exposures in lithography, it is typically desirable to provide radiation with high stability, for example fluctuations in beam size, beam shape and beam position. Therefore, providing a laser system with an optical system as described herein in combination with a lithographic apparatus can optimize the characteristics and improve the stability of a laser beam provided to the lithographic apparatus.

In a lithographic apparatus, the laser beam output from the laser system typically travels through one or more illumination system (e.g. the illuminator IL of FIG. 1A) which act to propagate the laser beam around the lithographic apparatus and/or condition the beam. Instabilities in the laser beam may affect the imaging characteristics of such an illumination system. In a known lithographic apparatus, standard illumination systems may be unable to propagate and/or condition a laser beam with a low stability effectively or at all. For example, given an unstable laser beam, an illumination system may be unable to attain a desired illumination mode. As such, the inclusion of additional components which increase the actual propagation distance of the laser beam in the laser system (and hence increase the instability of the laser beam at the output of the laser system) may require adjustments to or replacement of the illumination systems. Such adjustments or replacements may be costly and/or time consuming. The provision of a laser system as described herein may allow the increased actual propagation distance while retaining a high enough stability that original illumination systems may still be used to obtain an optimal lithographic exposure.

Some lasers experience speckle wherein a speckle pattern (e.g. a random variation in beam intensity) may be seen in the beam profile. The speckle pattern may be superimposed upon the beam profile as a perturbation to a nominal beam profile, for example a beam profile may have a generally Gaussian nominal profile with a speckle variation superimposed upon the Gaussian distribution of intensity. Speckle is particularly common in lasers with high coherence and/or lasers which emit radiation with a narrow bandwidth (e.g. less than a picometer).

Such narrow bandwidth lasers are desirable for use in lithographic apparatus. In lithography, speckle in a laser beam may cause the dose of radiation provided to the substrate to vary significantly (for example by a few percent compared to the desired dose). In lithography, speckle in a laser may negatively affect the ability of an illumination system to perform effectively, for example resulting in a sub-optimal illumination mode and/or sub-optimal dose control. Such dose variation and/or sub-optimal illumination modes may lead to sub-optimal lithographic exposure. For example, these dose errors and sub-optimal illumination modes may affect critical dimension uniformity (CDU).

A pulse stretcher may be used to reduce the effect of speckle when using a pulsed laser. The pulse stretcher converts a single laser pulse into a pulse train of secondary pulses. Each secondary pulse has a different speckle pattern, so the overall speckle of the entire pulse is at least partially averaged out. That is, the time-averaged speckle pattern of the entire pulse chain is smaller in magnitude compared to the initial pulse.

As described above, the use of an additional component such as a pulse stretcher can require the path length (i.e. actual propagation distance) of the laser beam in a laser system to be increased due to constraints in positioning the pule stretcher. Such an increased propagation distance would lead to sub-optimal laser beam characteristics at an output of the laser system and/or at the input of a lithographic apparatus. As such, the optical system described herein is particularly beneficial when used in a laser system with a pulse stretcher.

An example pulse stretcher comprises a beam splitter and a delay line comprising an arrangement of beam diverting elements (e.g. mirrors) that define a closed loop propagation path from and back to the beam splitter. In particular, the delay line is arranged to receive a portion of a pulse of radiation and return said portion of a pulse of radiation to the beam splitter after a delay time. In this way the delay line may be considered to form a closed loop or circular path to and from the beam splitter. The beam splitter receives an initial pulse and separates it into a first portion (i.e. a first secondary pulse) and a second portion (i.e. a second secondary pulse). The first secondary pulse is passed to an output of the pulse stretcher. The second secondary pulse is passed to the delay line. The delay line directs the second secondary pulse along a delay path and subsequently back to the beam splitter. When the beam splitter receives the second secondary pulse, it separates it into third and fourth secondary pulses. The third secondary pulse is passed to the output of the pulse stretcher, and arrives at the output at a time delayed with respect to the first secondary pulse (the delay time is determined by the length of the delay path of the delay line). The fourth secondary pulse is passed to the delay line and subsequently propagates along the delay path in the same manner as the second secondary pulse. Each time a secondary pulse propagates along the delay path and back to the beam splitter it is delayed by a delay time with respect to a preceding secondary pulse. By using this arrangement, secondary pulses circulate along the delay path multiple times, with each circulation adding an additional temporal delay with respect to the first smaller pulse. The subsequent output of the pulse stretcher is a chain of secondary pulses, each secondary pulse being temporally delayed from a preceding secondary pulse by a delay time determined by the delay line.

It should be understood that, while the chain of secondary pulses itself comprises multiple pulses, it is considered a single pulse with extended pulse length (extended with respect to the initial pulse). A single pulse can be considered temporally separated from a neighboring single pulse by a time designated by the laser (i.e. the repetition rate). A gap (temporal separation) between secondary pulses within a single pulse may occur, but the gap between secondary pulses is significantly less than the repetition rate of the laser.

The delay line is described as comprising a closed loop or circular arrangement of beam diverting elements. The term circular or loop used in this context is to illustrate that portions of the laser beam (e.g. secondary pulses) circulate around the elements in the pulse stretcher one or more times. It will be evident to a skilled person that light propagates linearly and hence a circular arrangement comprises a series of linear paths which collaborate to direct a laser beam around a closed loop. For example, if the delay line comprises a first, second, third and fourth mirrors, a portion of the laser beam may propagate through the pulse stretcher to the following components, in order: the beam splitter, the first mirror, the second mirror, the third mirror, the fourth mirror, the beam splitter (a second time), the first mirror (a second time), the second mirror (a second time) the third mirror (a second time), the fourth mirror (a second time), the beam splitter (a third time), the pulse stretcher output. The beam splitting and circular arrangement of the pulse stretcher is important for the pulse stretcher's purpose of delaying portions of a pulse. This is in contrast to the optical system as described herein, which has a linear arrangement such that the laser beam propagates to each component of the optical system (i.e. the first optical element and second optical element) only once before being output from the laser system. That is, the laser beam travels to the first optical element, second optical element, and output sequentially (in order) and linearly (not circulating). The laser beam travelling linearly may also be referred to as travelling singly as the laser beam does not pass to/through the first optical element, second optical element or output more than once.

The optical system described herein has no beam splitter directly prior to the first optical element such that substantially all of the laser beam (received either from the laser or from a component preceding the optical system e.g. a pulse stretcher) is received by the first optical element of the optical system. It should be understood that the term ‘substantially all’ is used as there will always be some losses in optical systems, for example optical elements may absorb a small portion (e.g. 0-2%) of a laser beam.

The pulse stretcher may comprise focusing elements, for example located along the delay line. However, the overall focusing power of the pulse stretcher is typically zero, that is it has a magnification of 1 or −1. With such an arrangement, the pulse stretcher can have an effective propagation length of zero.

When using a pulse stretcher, it may be particularly advantageous to position the optical system after the pulse stretcher (that is, between the pulse stretcher and the output rather than between the pulse stretcher and the laser. Such an arrangement is illustrated in FIG. 3 wherein the optical system 320 is positioned after the pulse stretcher 360 (i.e. positioned such that it receives the laser beam 320 after it has propagated through the pulse stretcher 360). This arrangement can result in reduced damage to optical components (for example lenses 331, 332) as the peak power (and peak energy) of a stretched pulse is less than the peak power/energy of an initial (un-stretched) pulse. Therefore, by positioning the optical system 320 after the pulse stretcher 360, a lower peak power of radiation is incident on the optical elements 331, 332 of the optical system 320.

In another example laser system, a second pulse stretcher is used. In this laser system, the first pulse stretcher is positioned between the laser and the optical system and the second pulse stretcher is positioned after the optical system (i.e. between the optical system and the output of the laser system). In this arrangement, the second optical element of the optical system is positioned proximal to an input of the second pulse stretcher. As the optical system can image a plane before the optical system to a conjugate plane after the optical system (these mutually conjugate planes being separated by a distance of four times the focal length of the two optical elements), the second optical element does not need to be positioned at one focal length from the input of the second pulse stretcher. Rather, the second optical element can be positioned less than one focal length from the input of the second pulse stretcher, thereby allowing the 4f distance to be maximized. In this arrangement, the laser beam travels indirectly between the second optical element and the output of the laser system, i.e. the laser beam travels to the second optical element, to the second pulse stretcher, and then to the output.

In another example laser system, a pulse stretcher is positioned between the first optical element and the second optical element of the laser system. For some requirements, for example specific space constraints, this arrangement may be beneficial. A pulse stretcher, or other additional component, may be positioned between the first and second optical element if the additional component provides no overall focusing power to the laser beam, for example if the total magnification of the additional component is 1 (or −1).

Reference has been made herein to distances, for example a distance between an image plane and an object plane. Unless specifically described otherwise, such references may be considered distances in a direction of propagation of the laser beam. It should be understood that a laser beam may be redirected, for example using mirrors, such that the direction of propagation of the laser beam may change. Distances measured in the direction of propagation of the laser beam may hence track the path propagated by the laser beam, including any redirection.

In some arrangements described herein, the second optical element is said to be proximal to the output of the laser system. In such arrangements, the second optical element may be located between the first optical element and the output of the laser system. Alternatively, the second optical element may coincide with the output of the laser system. In some arrangements, the laser system may have a housing and an exit aperture through which the laser beam may exit the laser system. In such an arrangement, the second optical element may be located outside of the housing such that the exit aperture is located between the first optical element and the second optical element. In this instance, the output of the laser system may be considered to coincide with the output of the laser system rather than the exit aperture corresponding to the output of the laser system.

The optical elements referred to herein may comprise lenses and/or mirrors. Spherical lenses may be used. In some arrangements, cylindrical lenses may be used, for example if only one dimension (e.g. the vertical portion) of the laser beam requires a reduction in effective propagation distance. Spherical lenses may be preferred due to their low cost, ease of implementation and/or symmetrical effect on the laser beam.

The laser systems described herein may allow the output laser beam of a laser system to have one or more desired characteristics. Specific reference has been made herein to the benefits of providing a reduced beam size at the output of the laser system. However, it should be understood that in some applications a larger beam size may be desirable. The laser systems described herein also provide an increased stability of a laser beam at an output of the laser system. It is typically desirable for a laser system to provide a stable output.

The laser system described herein may comprise a laser that produces radiation (i.e. in the laser beam 230, 330, 530) having a wavelength in the deep ultraviolet (DUV) range, for example, with wavelengths of 248 nanometres (nm) or 193 nm. The laser may comprise an excimer laser, for example an argon fluoride ArF laser or a krypton fluoride KrF laser.

Reference has been made herein, for example in reference to FIG. 3 and FIG. 5, of the use of a pulse stretcher. It should be understood that this component is used for illustrative purposes, and that other components used to shape, control and/or otherwise process a laser beam may be used in combination with the optical system 230, 330, 530 described herein, alternatively to or in addition to a pulse stretcher. Examples of such other components which may be used in a laser system are described with reference to FIG. 1B, for example the bandwidth analysis module 175, pulse stretcher 180, metrology module 185.

Reference has been made herein to characteristics of a laser beam. The stability of a characteristic of the laser beam may also be considered a characteristic of the laser beam.

Reference has been made herein to optimal or optimized characteristics. The skilled person should understand that optimal may have a different meaning depending on the application. Optimal in a lithographic exposure may mean, for example, a high enough quality given the requirements of the lithographic exposure. Optimal in some applications may be interpreted as improved compared to a less optimal example.

It will be appreciated that in the context of a laser beam or radiation beam the term travels is synonymous with the term propagates and these two terms (and derivations thereof such as travelling and propagating) may be used interchangeably herein.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to the use of the laser system in the context of a lithographic apparatus, it may be used in other apparatus. For example, the laser system may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions. Alternatively, embodiments of the invention may be used in any apparatus which uses laser radiation, whether related to lithography or otherwise.

The embodiments can be further described using the following clauses:
1. A laser system comprising:
a laser operable to generate a laser beam;
an optical system comprising a first optical element and a second optical element; and
an output through which the laser beam exits the laser system;
the laser, optical system and output arranged such that the laser beam propagates to the first optical element, the second optical element and the output sequentially;
wherein the first optical element has a first focal length, the second optical element has a second focal length equal to the first focal length, and the second optical element is spaced from the first optical element by a distance of two times the first focal length.
2. The laser system of clause 1, wherein the laser comprises an excimer laser.
3. The laser system of clause 1 or 2, further comprising a pulse stretcher for increasing a pulse length of a pulse in the laser beam.
4. The laser system of clause 3 wherein the pulse stretcher is arranged between the laser and the first optical element.
5. The laser system of clause 3 or 4 wherein the pulse stretcher comprises a pulse stretcher output through which a pulse of increased pulse length may exit the pulse stretcher, and wherein the first optical element is located proximal to the pulse stretcher output.
6. The laser system of clause 5, wherein the distance between the pulse stretcher output and the first optical element is less than the first focal length.
7. The laser system of any preceding clause wherein the second optical element receives the laser beam directly from the first optical element.
8. The laser system of any preceding clause further comprising a housing within which the laser and the optical system are disposed, wherein:
the housing has an exit aperture at or proximal to the output of the laser system; and
the second optical element is located proximal to the exit aperture.
9. The laser system of clause 8, wherein the distance between the exit aperture and the second optical element is less than the first focal length.
10. The laser system of any preceding clause further comprising:
a second optical system comprising a third optical element and a fourth optical element;
wherein the third optical element has a third focal length, the fourth optical element has a fourth focal length equal to the third focal length, and the fourth optical element is spaced from the third optical element along the optical axis by a distance of two times the third focal length.
11. The laser system of any preceding clause further comprising a second pulse stretcher.
12. A lithographic apparatus comprising the laser system of any preceding clause
13. A laser system comprising:
a laser operable to generate a laser beam;
an optical system comprising a first optical element and a second optical element; and
an output through which the laser beam exits the laser system;
the laser, optical system and output arranged such that the laser beam propagates to the first optical element, the second optical element and the output sequentially;
wherein the first optical element has a first focal length, the second optical element has a second focal length, and the second optical element is spaced from the first optical element by a distance substantially equal to the sum of the first focal length and the second focal length.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A laser system comprising:
a laser operable to generate a laser beam;
an optical system comprising a first optical element and a second optical element; and
an output through which the laser beam exits the laser system;
the laser, optical system and output arranged such that the laser beam propagates to the first optical element, the second optical element and the output sequentially;
wherein the first optical element has a first focal length, the second optical element has a second focal length equal to the first focal length, and the second optical element is spaced from the first optical element by a distance of two times the first focal length.

2. The laser system of claim 1, wherein the laser comprises an excimer laser.

3. The laser system of claim 2, further comprising a pulse stretcher for increasing a pulse length of a pulse in the laser beam.

4. The laser system of claim 3 wherein the pulse stretcher is arranged between the laser and the first optical element.

5. The laser system of claim 4, wherein the pulse stretcher comprises a pulse stretcher output through which a pulse of increased pulse length may exit the pulse stretcher, and wherein the first optical element is located proximal to the pulse stretcher output.

6. The laser system of claim 1, further comprising a pulse stretcher for increasing a pulse length of a pulse in the laser beam.

7. The laser system of claim 6, wherein the pulse stretcher is arranged between the laser and the first optical element.

8. The laser system of claim 7, wherein the pulse stretcher comprises a pulse stretcher output through which a pulse of increased pulse length may exit the pulse stretcher, and wherein the first optical element is located proximal to the pulse stretcher output.

9. The laser system of claim 8 wherein a distance between the pulse stretcher output and the first optical element is less than the first focal length.

10. The laser system of claim 1, wherein the second optical element receives the laser beam directly from the first optical element.

11. The laser system of claim 1, further comprising a housing within which the laser and the optical system are disposed, wherein:
the housing has an exit aperture at or proximal to the output of the laser system; and
the second optical element is located proximal to the exit aperture.

12. The laser system of claim 11, wherein the distance between the exit aperture and the second optical element is less than the first focal length.

13. The laser system of claim 1, further comprising:
a second optical system comprising a third optical element and a fourth optical element;
wherein the third optical element has a third focal length, the fourth optical element has a fourth focal length equal to the third focal length, and the fourth optical element is spaced from the third optical element along the optical axis by a distance of two times the third focal length.

14. The laser system of claim 8, further comprising a second pulse stretcher.

15. A lithographic apparatus comprising:
a laser system comprising:
a laser operable to generate a laser beam;
an optical system comprising a first optical element and a second optical element; and
an output through which the laser beam exits the laser system;
the laser, optical system and output arranged such that the laser beam propagates to the first optical element, the second optical element and the output sequentially;
wherein the first optical element has a first focal length, the second optical element has a second focal length equal to the first focal length, and the second optical element is spaced from the first optical element by a distance of two times the first focal length.

16. The lithographic apparatus of claim 15, further comprising a pulse stretcher for increasing a pulse length of a pulse in the laser beam, wherein
the pulse stretcher is arranged between the laser and the first optical element and the pulse stretcher comprises a pulse stretcher output through which a pulse of increased pulse length may exit the pulse stretcher, and wherein the first optical element is located proximal to the pulse stretcher output.

17. The lithographic apparatus of claim 15, further comprising a housing within which the laser and the optical system are disposed, wherein:
the housing has an exit aperture at or proximal to the output of the laser system; and
the second optical element is located proximal to the exit aperture.

18. The lithographic apparatus of claim 17, wherein the distance between the exit aperture and the second optical element is less than the first focal length.

19. A laser system comprising:
a laser operable to generate a laser beam;
an optical system comprising a first optical element and a second optical element; and
an output through which the laser beam exits the laser system;
the laser, optical system and output arranged such that the laser beam propagates to the first optical element, the second optical element and the output sequentially;
wherein the first optical element has a first focal length, the second optical element has a second focal length, and the second optical element is spaced from the first optical element by a distance substantially equal to the sum of the first focal length and the second focal length.
